(19) United States
(12) Patent Application Publication
(10) Pub. No.: US 2026/0096162 A1
(43) Pub. Date: Apr. 2, 2026

(54) ARSENIC-DOPED SOURCE/DRAIN WITH PHOSPHORUS-DOPED CONTACT REGION FOR DOPANT DIFFUSION CONTROL

(71) Applicant: Intel Corporation, Santa Clara, CA (US)

(72) Inventors: Patrick M. Wallace, Hillsboro, OR (US); Robert Ehlert, Portland, OR (US); William Hsu, Portland, OR (US); Ethan James Nagasing, Portland, OR (US); Sandrine Charue-Bakker, Portland, OR (US); Amritesh Rai, Tigard, OR (US); Chang Wan Han, Portland, OR (US); Yulia Tolstova, Hillsboro, OR (US); Chi-Hing Choi, Portland, OR (US); Swapnadip Ghosh, Hillsboro, OR (US)

(73) Assignee: Intel Corporation, Santa Clara, CA (US)

(21) Appl. No.: 18/899,866

(22) Filed: Sep. 27, 2024

(51) Int. Cl. H01L 29/08; H01L 21/822; H01L 21/8238; H01L 27/06; H01L 27/092; H01L 29/06; H01L 29/423; H01L 29/778; H01L 29/786

(52) U.S. Cl. CPC H10D 62/151; H10D 30/47; H10D 30/6735; H10D 30/6757; H10D 62/118; H10D 84/0167; H10D 84/017; H10D 84/0193; H10D 84/038; H10D 84/853; H10D 84/856; H10D 88/00; H10D 88/01

(57) ABSTRACT

Semiconductor devices and systems with arsenic-doped sources and drains that include phosphorus-doped contact regions, and methods of forming the same, are disclosed herein. In one example, a semiconductor device includes an epitaxial structure and a conductive contact. The epitaxial structure includes silicon, arsenic, and phosphorus, where phosphorus is concentrated in a contact region of the epitaxial structure. The conductive contact is coupled to the contact region of the epitaxial structure, and the conductive contact includes metal.

### BACKGROUND

Phosphorus is a commonly used n-type dopant in Group IV semiconductors due to its relative ease of incorporation and the low resistivity of the resultant films. However, phosphorus is not ideal for bulk doping due to its fast diffusion through silicon at elevated temperatures. This rapid diffusivity is of particular concern in the source/drain of modern n-type metal-oxide- semiconductor (NMOS) transistors, where the concentration of phosphorus in silicon is far above the solubility limit, which leads to excessive phosphorus diffusion into neighboring layers, such as the transistor channel. This is undesirable, as phosphorus diffusion can reduce electron mobility via carrier scattering and can also form low-resistivity leakage paths under the gate.

By contrast, the diffusivity of arsenic is about 10 times lower than phosphorus, and arsenic also has an atomic radius very close to that of silicon, which permits a much higher solubility while maintaining crystallinity. However, arsenic is difficult to activate without high-temperature anneals, and as a result, bulk resistivity is higher in arsenic-doped films than in equivalent phosphorus-doped films.

### BRIEF DESCRIPTION OF THE DRAWINGS

FIG. 1 illustrates a cross-section view of a transistor that includes arsenic-doped source/drain structures with phosphorus implants in the contact region.

FIGS. 2A-J illustrate a process flow for forming a transistor that includes arsenic-doped source/drain structures with phosphorus implants in the contact region.

FIG. 3 illustrates a cross-section view of a transistor that includes arsenic-doped source/drain structures with a phosphorus-doped capping layer in the contact region.

FIGS. 4A-J illustrate a process flow for forming a transistor that includes arsenic-doped source/drain structures with a phosphorus-doped capping layer in the contact region.

FIG. 5 illustrates a cross-section view of another transistor that includes arsenic-doped source/drain structures with phosphorus implants in the contact region.

FIG. 6 illustrates a cross-section view of another transistor that includes arsenic-doped source/drain structures with a phosphorus-doped capping layer in the contact region.

FIG. 7 illustrates a flowchart for forming semiconductor devices that include arsenic-doped source/drain structures with phosphorus-doped contact regions.

FIG. 8 illustrates a top view of a wafer and dies that may be included in a microelectronic assembly.

FIG. 9 illustrates a cross-sectional side view of an integrated circuit device that may be included in a microelectronic assembly.

FIGS. 10A-D illustrate perspective views of example planar, FinFET, gate-all-around, and stacked gate-all-around transistors.

FIG. 11 illustrates a cross-sectional side view of an integrated circuit device assembly that may include a microelectronic assembly.

FIG. 12 illustrates a block diagram of an example electrical device that may include a microelectronic assembly.

### DETAILED DESCRIPTION

Phosphorus is a commonly used n-type dopant in Group IV semiconductors due to its relative ease of incorporation and the low resistivity of the resultant films. However, phosphorus is not ideal for bulk doping, as it diffuses through silicon relatively easily at elevated temperatures due to its relatively small size. This rapid diffusivity is of particular concern in device regions that require high n-type doping, such as the source/drain regions of modern n-type metal-oxide- semiconductor (NMOS) transistors, where the concentration of phosphorus in silicon is far above the solubility limit, which leads to excessive phosphorus diffusion into neighboring layers that are intended to remain undoped, such as a transistor channel or subfin. This is undesirable, as phosphorus diffusion can reduce electron mobility via carrier scattering and can also form low-resistivity leakage paths under the gate. In modern gate-last process flows, the NMOS source/drain regions are deposited before the gate oxides, which leaves several high-temperature opportunities in the process flow for phosphorus to diffuse.

By contrast, the diffusivity of arsenic is much lower than that of phosphorus, which enables higher doping levels with less diffusion into the channel and other neighboring regions than with phosphorus. In particular, the diffusivity of arsenic is about 10 times lower than phosphorus, and arsenic also has an atomic radius very close to that of silicon, which permits a much higher solubility while maintaining crystallinity. However, arsenic is difficult to activate without high-temperature anneals, and as a result, bulk resistivity is higher in arsenic-doped films than in equivalent phosphorus-doped films.

In some cases, source/drain epis may be formed with low phosphorus doping as grown to reduce phosphorus diffusion throughout the high-temperature processing steps, followed by an implant or epi regrowth to increase the phosphorus dopant concentration later in the process flow. While decreasing the phosphorus dopant concentration as grown may help reduce phosphorus diffusion, the resulting diffusion is still problematic, as the small concentration levels of diffused phosphorus needed to induce carrier scattering are still present.

Diffusion barriers can also be used to reduce phosphorus diffusion, such as layers of arsenic-doped silicon (Si:As) or silicon carbide (SiC). However, these diffusion barrier materials have higher resistivity than phosphorus-doped silicon (Si:P), and as a result, layers of these materials that are thick enough to reduce phosphorus diffusion typically have a negative impact on resistivity.

Accordingly, this disclosure presents embodiments of high-arsenic-doped source/drain structures with a phosphorus-doped contact region for dopant diffusion control, along with methods of forming the same. In particular, the high-arsenic-doped source/drain structures may include a phosphorus implant or cap in the contact region, which may be added later in the process flow, to reduce dopant diffusion during processing while maintaining low resistivity at the contact interface (e.g., the interface between the source/drain and associated source/drain metal contact).

In some embodiments, for example, NMOS source/drain structures may be formed with high arsenic doping as grown to avoid phosphorus dopant diffusion during high-temperature steps, and a phosphorus implant or capping layer may be added after the high-temperature steps to improve contact resistivity. In particular, high-arsenic-doped silicon may be produced as grown, which diffuses very little through high-temperature steps during very large-scale integration (VLSI) processing. Low contact resistivity may then be recovered downstream in the process flow after the high-temperature steps are complete by adding a phosphorus implant or phosphorus-doped silicon capping layer in the contact region.

In particular, arsenic-doped films have higher resistivity as grown compared to phosphorus-doped films, and the higher resistivity can negatively impact transistor drive. Thus, in this disclosure, various approaches are presented for reducing contact resistivity for arsenic doped n-type epitaxial layers. In particular, low contact resistivity can be recovered via phosphorus implant or a phosphorus-doped capping layer downstream in the process.

For example, with respect to the phosphorus implant approach, arsenic-doped silicon is epitaxially grown early in the process flow and carried through all high-temperature processing steps. Before the trench contact is formed, however, a phosphorus implant is added to the contact region of the arsenic-doped n-epi layer (e.g., via ion implantation), which reduces the resistivity of the n-epi layer and the epi-contact interface.

With respect to the phosphorus cap approach, the bulk of the n-epi layer is arsenic doped, but the n-epi layer is capped with a thin phosphorus-doped layer as grown before the trench contact is formed.

In this manner, the trench contact is made to the low-resistivity contact region of the n-epi layer—which includes either the phosphorus implant or the phosphorus-doped cap—thus maintaining low contact resistivity with the benefits of reduced dopant diffusion.

The described embodiments may provide various advantages. For example, the removal of phosphorus dopants during high-temperature processing steps significantly reduces the diffusion of phosphorus dopants into the channel. In some embodiments, for example, the concentration of diffused phosphorus dopants in the channel may be less than 1e¹⁸ atoms per cubic centimeter (atoms/cm³), which is not high enough to induce carrier scattering. Moreover, downstream resistivity recovery via phosphorus implant or capping layer reclaims the lower contact resistivity that phosphorus provides over arsenic, which reduces or eliminates any performance loss. High-arsenic-doped films also provide improved variability compared to phosphorus-doped films due to the similar atomic radius between arsenic and silicon, which enables reduced fin-to-fin spacing and improved integration with other processes that depend on epi uniformity, such as contact formation.

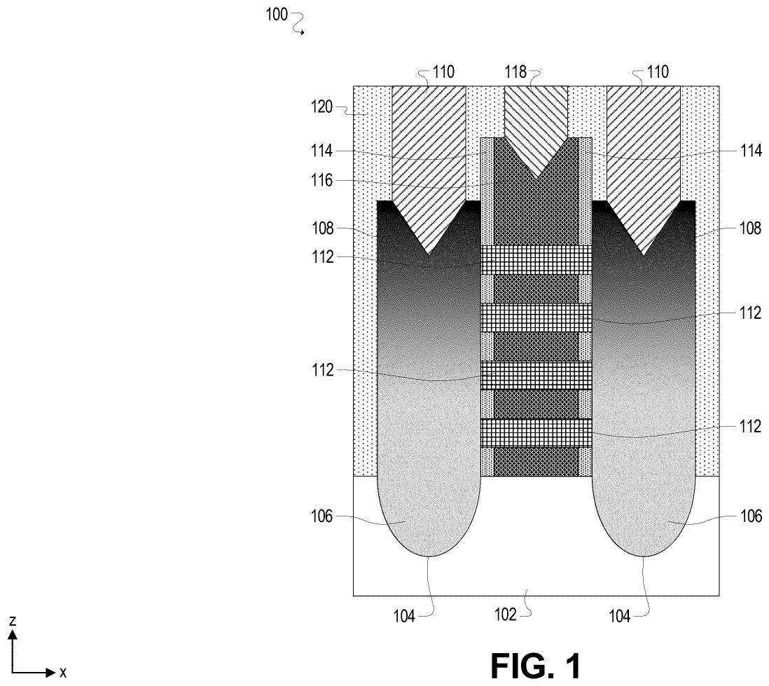

FIG. 1 illustrates a cross-section (x-z plane) view of a transistor 100 that includes arsenic-doped source/drain structures 104 with phosphorus implants in the contact region. In the illustrated embodiment, transistor 100 is an NMOS gate-all-around (GAA) transistor with n-type source/drain epitaxial structures 104. Moreover, the source/drain structures 104 include high-arsenic-doped silicon 106 throughout, along with implanted phosphorus ions 108 in the contact region, to reduce phosphorus diffusion during fabrication while still achieving low contact resistivity. In particular, the source/drain structures 104 are epitaxially grown with high-arsenic-doped silicon 106 (e.g., instead of phosphorus) to avoid phosphorus dopant diffusion during high-temperature steps (e.g., anneals). After the high-temperature steps are complete, and before the source/drain contacts 110 are formed, phosphorus implantation is performed to implant phosphorus ions 108 in the contact region of the source/drain structures 104, which reduces the resistivity of the contact region. In this manner, when the source/drain contacts 110 are formed, they make contact with the low-resistivity contact region where the phosphorus ions 108 were implanted, thus recovering the low contact resistivity that phosphorus provides over arsenic, while also significantly reducing dopant diffusion during processing due to the low diffusivity of arsenic versus phosphorus. As a result, the dopant diffusion into the channel is nominal (e.g., with substantially no diffused phosphorus), and low contact resistivity is maintained.

Another benefit of transistor 100 is improved variability in the site-to-site deposition thickness of the epitaxial source/drain structures 104 (e.g., more uniform epitaxial growth in the epi thickness or width along the y axis). In particular, sources/drains formed with arsenic-doped epitaxial deposition exhibit better site-to-site deposition thickness variability than phosphorus-doped or phosphorus/arsenic co-doped epitaxial deposition. The improved variability is a result of the similar atomic radius between arsenic and silicon, which results in lower defectivity at high doping concentrations.

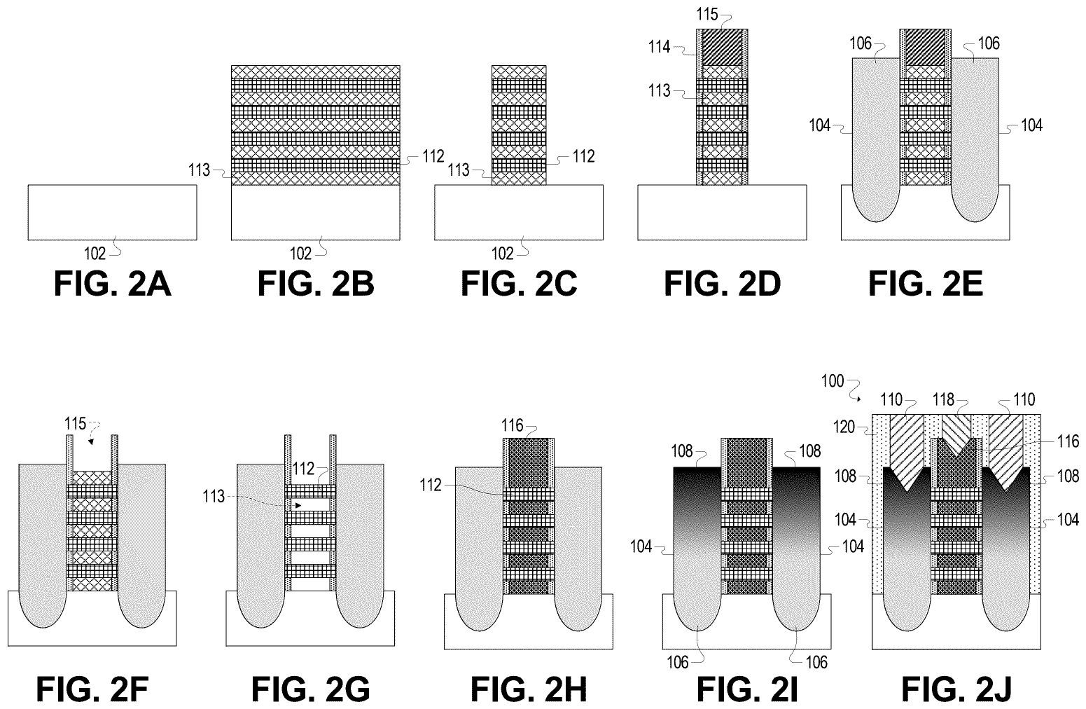

The process flow for forming transistor 100 is described in further detail below in connection with FIGS. 2A-J.

FIGS. 2A-J illustrate an example process flow for forming a transistor 100 that includes arsenic-doped source/drain structures with phosphorus implants in the contact region. In the illustrated example, FIGS. 2A-J show cross-section (x-z plane) views after performing various steps of the process flow. It will be appreciated in light of the present disclosure that the illustrated process flow is only one example methodology for arriving at a transistor that includes arsenic-doped source/drain structures with phosphorus implants.

In FIG. 2A, a substrate 102 is received. In some embodiments, the substrate 102 may include silicon (e.g., a silicon wafer).

In FIG. 2B, a superlattice is formed over the substrate 102. In the illustrated embodiment, the superlattice includes a stack of alternating layers of silicon germanium (SiGe) 113 and (undoped) silicon (Si) 112. In subsequent steps of the process flow, the layers of silicon 112 will be used to form the channel (e.g., silicon nanoribbons, nanowires, nanosheets) of the transistor, while the layers of silicon germanium 113 will be removed and replaced with the gate. In other embodiments, the layers of the superlattice may include other types or combinations of materials.

In FIG. 2C, the SiGe/Si superlattice layers 113, 112 are patterned into a fin. In particular, the superlattice layers 113, 112 are etched down to the substrate 102 in areas where the source/drain structures will be formed.

In FIG. 2D, a dummy gate 115 is formed above the superlattice stack 113, 112, and a gate spacer 114 is formed on the sides of the dummy gate 115 and the SiGe superlattice layers 113. The gate spacer 114 may include a dielectric material. In subsequent steps of the process flow, the dummy gate 115 will be replaced with the actual gate, and the gate spacer 114 will serve as sidewalls on the gate to create separation between the gate and the source/drain structures.

In FIG. 2E, source/drain regions 104 are formed on opposite sides of the superlattice stack. In the illustrated embodiment, the source/drain regions 104 include arsenic-doped epitaxial structures 106, which are epitaxially grown using silicon doped with a relatively high concentration of arsenic, referred to herein as high-arsenic-doped silicon. In some embodiments, for example, the concentration of arsenic may be in the range of 1e²⁰ to 7e²¹ atoms per cubic centimeter (atoms/cm³), but preferably over 5e²¹ atoms/cm³. Moreover, the concentration of arsenic may be substantially uniform throughout the arsenic-doped epitaxial structures 106.

In FIG. 2F, the dummy gate 115 is removed or etched away.

In FIG. 2G, the sacrificial SiGe layers 113 are etched away to release the silicon layers 112, thus forming silicon channel structures 112 extending between the source/drain regions 104 (e.g., nanoribbons, nanowires, or nanosheets), which collectively form the transistor channel 112.

In FIG. 2H, a gate 116 is formed over/around the silicon channel structures 112. In some embodiments, for example, the gate 116 may be formed by depositing and patterning a high-k dielectric material (e.g., an oxide) and a gate metal (e.g., tungsten) around the channel structures 112 (e.g., filling the area previously occupied by the SiGe layers 113).

In FIG. 2I, a phosphorus implant 108 is formed in the contact region of the respective source/drain structures 104. In particular, the contact region refers to the region of the respective source/drain structures 104 where source/drain contacts 110 will make contact with the source/drain structures 104 (e.g., the portion of the source/drain structures 104 adjacent to or near the contact interface between the source/drain structures 104 and the source/drain contacts 110).

In some embodiments, for example, phosphorus ions 108 may be implanted in the contact region of the respective source/drain structures 104 via ion implantation. Implanted ions generally follow a Gaussian distribution profile, where most of the ions accumulate around the same depth (e.g., based on the energy of the implanted ions), while some spread slightly deeper and slightly shallower. In this manner, the distribution of the phosphorus ions in the contact region of the source/drain structures 104 (e.g., along the z axis) may be approximately Gaussian.

Moreover, in some cases, the source/drain structures 104 may have defects resulting from the ion implants. For example, phosphorus ions 108 may penetrate the silicon lattice with sufficient energy to knock silicon atoms out of their positions, which may produce vacancies, interstitials, and other defects that may disturb the crystalline order of the silicon.

After the phosphorus implant 108 is complete, the bulk of the source/drain epi structures 104 includes arsenic-doped silicon 106 (e.g., with a substantially uniform concentration of arsenic), but the contact region also includes phosphorus ions 108 implanted in the arsenic-doped silicon 106 (e.g., such that the phosphorus ions 108 are concentrated in the contact region of the source/drain structures 104). Thus, the contact region of the source/drain structures 104 includes silicon doped with arsenic and phosphorus.

In FIG. 2J, conductive (e.g., metal) source/drain contacts 110 are formed over the source/drain structures 104, such that the respective source/drain contacts 110 make contact with the respective source/drain structures 104 at the contact interface (e.g., the interface between the source/drain structures 104 and the source/drain contacts 110) and further extend into the contact region of the respective source/drain structures 104, which is the region where the phosphorus implant 108 was formed. In this manner, low contact resistivity (e.g., the resistivity between the source/drain structures 104 and source/drain contacts 110) is recovered through the phosphorus implant 108.

Further, a conductive (e.g., metal) gate contact 118 is similarly formed over the gate 116. The remaining areas are filled with one or more inter-layer dielectrics (ILDs) 120.

At this point, transistor 100 may be complete. In the illustrated embodiment, the completed transistor 100 includes source/drain epitaxial regions 104 with arsenic-doped silicon epitaxial structures 106 and phosphorous implants 108 (e.g., implanted phosphorus ions), channel 112, gate 116, conductive source/drain contacts 110, and conductive gate contact 118.

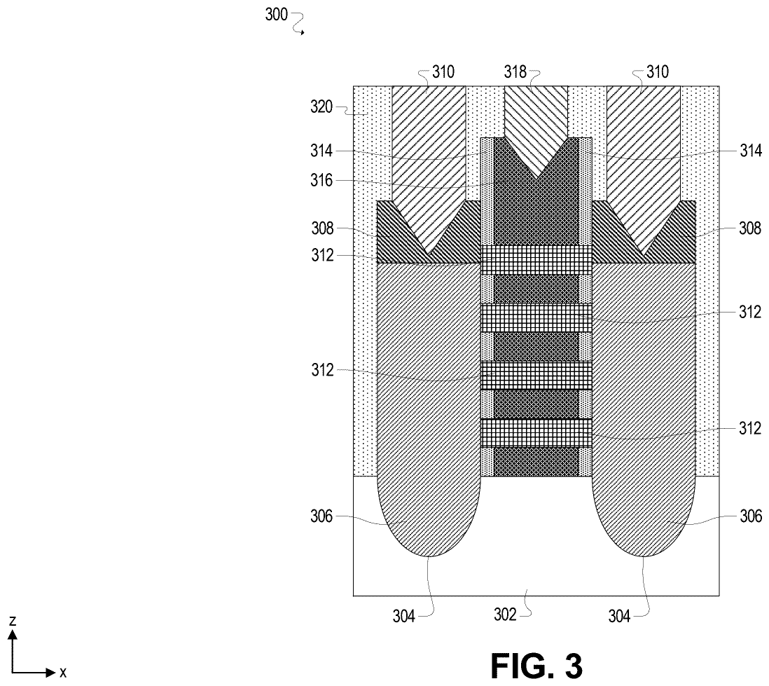

FIG. 3 illustrates a cross-section (x-z plane) view of a transistor 300 that includes arsenic-doped source/drain structures 304 with a phosphorus-doped cap in the contact region. In particular, transistor 300 is similar to transistor 100, except the source/drain structures 304 include a phosphorus-doped capping layer 308 to recover low contact resistivity instead of phosphorus implants 108. In the illustrated embodiment, for example, transistor 300 is an NMOS gate-all-around (GAA) transistor with n-type source/drain epitaxial structures 304. Moreover, the respective source/drain structures 304 include two distinct layers/regions: a larger layer/region 306 with high-arsenic-doped silicon throughout, and a smaller layer/region 308 with phosphorus-doped silicon throughout, which is referred to herein as the phosphorus cap or phosphorus-doped capping layer. The phosphorus cap 308, which serves as the contact region of the source/drain structures 304, helps to reduce phosphorus diffusion during fabrication while still achieving low contact resistivity. In particular, the arsenic-doped layer 306 is epitaxially grown with high-arsenic-doped silicon (e.g., instead of phosphorus) to avoid phosphorus dopant diffusion during high-temperature steps (e.g., anneals). After the high-temperature steps are complete, and before the source/drain contacts 310 are formed, the phosphorus-dopped capping layer 308 is epitaxially grown with phosphorus-doped silicon on top of the arsenic-doped layer 306—where the contact region is located—which reduces the resistivity of the contact region. In this manner, when the source/drain contacts 310 are formed, they make contact with the contact region in the low-resistivity capping layer 308, thus recovering the low contact resistivity that phosphorus provides over arsenic, while also significantly reducing dopant diffusion during processing due to the low diffusivity of arsenic versus phosphorus. As a result, the dopant diffusion into the channel is nominal (e.g., with substantially no diffused phosphorus), and low contact resistivity is maintained.

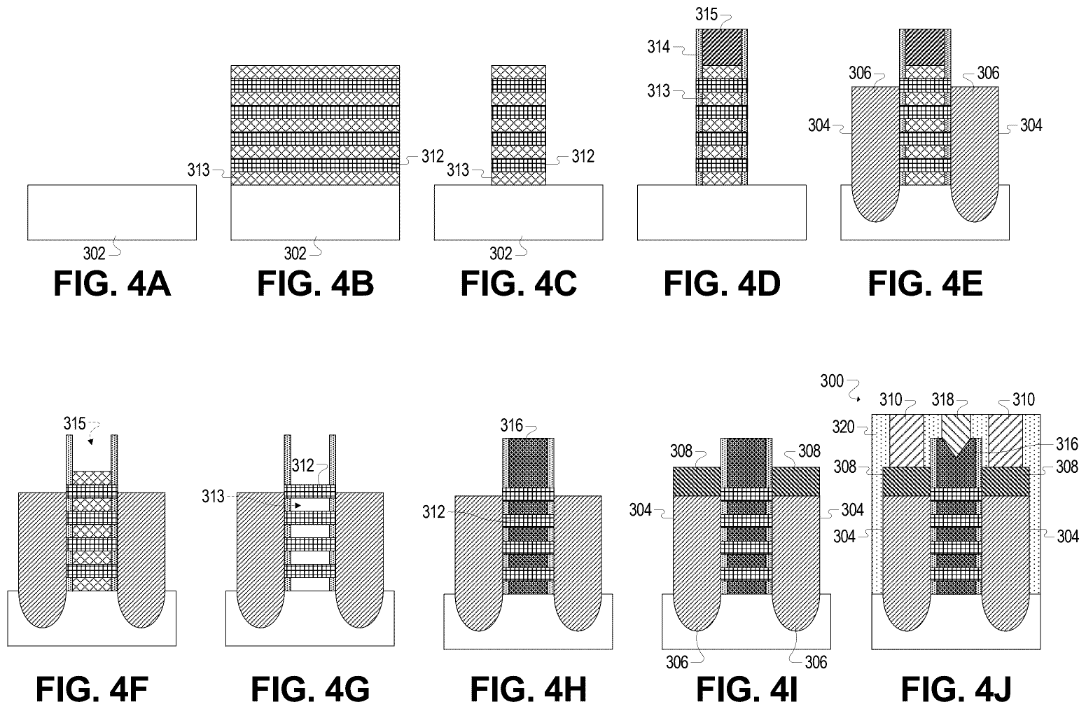

The process flow for forming transistor 300 is described in further detail below in connection with FIGS. 4A-J.

FIGS. 4A-J illustrate an example process flow for forming a transistor 300 that includes arsenic-doped source/drain structures with a phosphorus-doped capping layer in the contact region. In the illustrated example, FIGS. 4A-J show cross-section (x-z plane) views after performing various steps of the process flow. It will be appreciated in light of the present disclosure that the illustrated process flow is only one example methodology for arriving at a transistor that includes arsenic-doped source/drain structures with a phosphorus capping layer.

In FIG. 4A, a substrate 302 is received. In some embodiments, the substrate 302 may include silicon (e.g., a silicon wafer).

In FIG. 4B, a superlattice is formed over the substrate 302. In the illustrated embodiment, the superlattice includes a stack of alternating layers of silicon germanium (SiGe) 313 and (undoped) silicon (Si) 312. In subsequent steps of the process flow, the layers of silicon 312 will be used to form the channel (e.g., silicon nanoribbons, nanowires, nanosheets) of the transistor, while the layers of silicon germanium 313 will be removed and replaced with the gate. In other embodiments, the layers of the superlattice may include other types or combinations of materials.

In FIG. 4C, the SiGe/Si superlattice layers 313, 312 are patterned into a fin. In particular, the superlattice layers 313, 312 are etched down to the substrate 302 in areas where the source/drain structures will be formed.

In FIG. 4D, a dummy gate 315 is formed above the superlattice stack 313, 312, and a gate spacer 314 is formed on the sides of the dummy gate 315 and the SiGe superlattice layers 313. The gate spacer 314 may include a dielectric material. In subsequent steps of the process flow, the dummy gate 315 will be replaced with the actual gate, and the gate spacer 314 will serve as sidewalls on the gate to create separation between the gate and the source/drain structures.

In FIG. 4E, source/drain regions 304 are formed on opposite sides of the superlattice stack. In the illustrated embodiment, the source/drain regions 304 include arsenic-doped epitaxial structures 306, which are epitaxially grown using silicon doped with a relatively high concentration of arsenic, referred to herein as high-arsenic-doped silicon. In some embodiments, for example, the concentration of arsenic may be in the range of 1e²⁰ to 7e²¹ atoms per cubic centimeter (atoms/cm³), but preferably over 5e²¹ atoms/cm³. Moreover, the concentration of arsenic may be substantially uniform throughout the arsenic-doped epitaxial structures 306.

In the illustrated embodiment, the arsenic-doped epitaxial structures 306 are shorter than they otherwise would be, as phosphorus-doped epitaxial layers will be added on top of them in subsequent steps of the process flow.

In FIG. 4F, the dummy gate 315 is removed or etched away.

In FIG. 4G, the sacrificial SiGe layers 313 are etched away to release the silicon layers 312, thus forming silicon channel structures 312 extending between the source/drain regions 304 (e.g., nanoribbons, nanowires, or nanosheets), which collectively form the transistor channel 312.

In FIG. 4H, a gate 316 is formed over/around the silicon channel structures 312. In some embodiments, for example, the gate 316 may be formed by depositing and patterning a high-k dielectric material (e.g., an oxide) and a gate metal (e.g., tungsten) around the channel structures 312 (e.g., filling the area previously occupied by the SiGe layers 313).

In FIG. 4I, a phosphorus-doped epitaxial capping layer 308 is formed on top of the arsenic-doped epitaxial structures/layers 306 in the respective source/drain regions 304 (e.g., resulting in a sharp interface between the arsenic-doped layers 306 and the phosphorus-doped caps 308). In some embodiments, for example, the capping layer 308 may be epitaxially grown using silicon doped with phosphorus (e.g., with a substantially uniform concentration of phosphorus). Moreover, in some embodiments, the thickness of the capping layer 308 may be in the range of 10%-40% of the thickness of the arsenic-doped epitaxial layer 306. Further, since the capping layer 308 is formed over the arsenic-doped epis 306, the capping layer 308 serves as the contact region of the respective source/drain structures 304.

In FIG. 4J, conductive (e.g., metal) source/drain contacts 310 are formed over the source/drain structures 304, such that the respective source/drain contacts 310 make contact with the respective source/drain structures 304 at the contact interface (e.g., the interface between the source/drain structures 304 and the source/drain contacts 310) and further extend into the contact region of the respective source/drain structures 304, which is the region occupied by the phosphorus cap 308. In this manner, low contact resistivity (e.g., the resistivity between the source/drain structures 304 and source/drain contacts 310) is recovered through the phosphorus cap 308.

Further, a conductive (e.g., metal) gate contact 318 is similarly formed over the gate 316. The remaining areas are filled with one or more inter-layer dielectrics (ILDs) 320.

At this point, transistor 300 may be complete. In the illustrated embodiment, the completed transistor 300 includes source/drain epitaxial regions 304 with arsenic-doped silicon epitaxial structures 306 and phosphorous-doped silicon epitaxial capping layers 308, channel 312, gate 316, conductive source/drain contacts 310, and conductive gate contact 318.

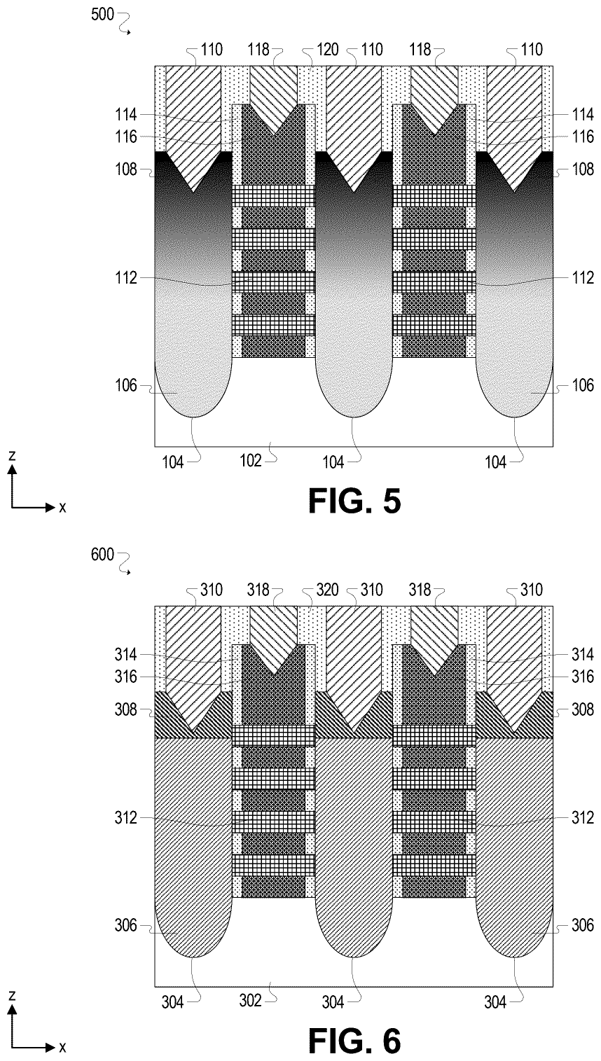

FIG. 5 illustrates a cross-section (x-z plane) view of another transistor 500 that includes arsenic-doped source/drain structures with phosphorus implants in the contact region. In the illustrated embodiment, transistor 500 is similar to transistor 100, except transistor 500 includes three source/drain regions 104 (and associated source/drain contacts 110), two sets of channel nanoribbons 112 extending between adjacent source/drain regions 104, and two gates 116 (and associated gate contacts 118) coupled to the respective sets of channel nanoribbons 112. In other embodiments, transistor 500 may be scaled to include additional source/drain regions 104, channels 112, and gates 116.

FIG. 6 illustrates a cross-section (x-z plane) view of another transistor 600 that includes arsenic-doped source/drain structures with a phosphorus-doped capping layer in the contact region. In the illustrated embodiment, transistor 600 is similar to transistor 300, except transistor 600 includes three source/drain regions 304 (and associated source/drain contacts 310), two sets of channel nanoribbons 312 extending between adjacent source/drain regions 304, and two gates 316 (and associated gate contacts 318) coupled to the respective sets of channel nanoribbons 312. In other embodiments, transistor 600 may be scaled to include additional source/drain regions 304, channels 312, and gates 316.

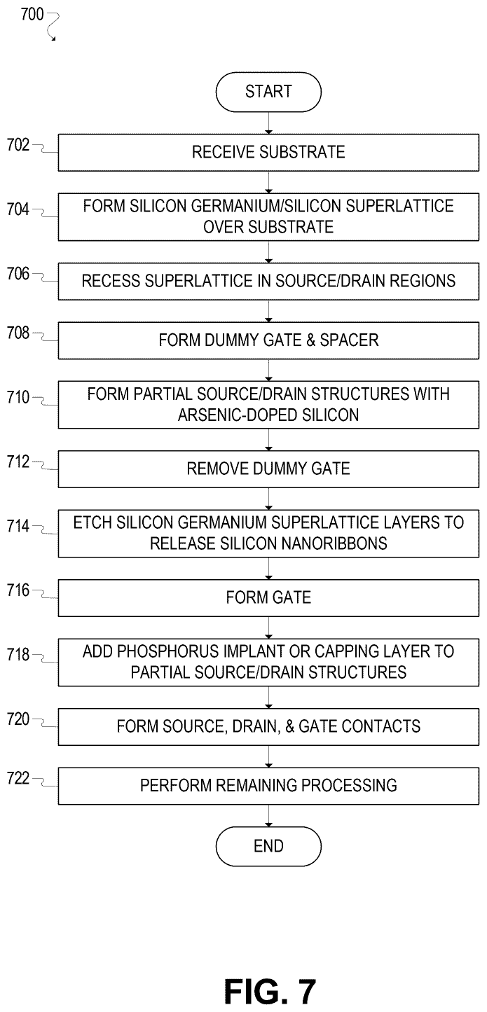

FIG. 7 illustrates a flowchart 700 for forming semiconductor devices that include arsenic-doped source/drain structures with phosphorus-doped contact regions (e.g., transistors 100, 300, 500, 600). It will be appreciated in light of the present disclosure that the illustrated process flow is only one example methodology for arriving at the example devices shown and described throughout this disclosure.

The steps of the illustrated process flow may be performed using any suitable semiconductor fabrication techniques. For example, film deposition—such as depositing layers, filling portions of layers (e.g., removed portions), and filling via openings—may be performed using any suitable deposition techniques, including, for example, chemical vapor deposition (CVD), metal-organic chemical vapor deposition (MOCVD), molecular beam epitaxy (MBE), atomic layer deposition (ALD), and/or physical vapor deposition (PVD). Moreover, patterning and removal—such as interconnect patterning, forming via openings, and shaping—may be performed using any suitable techniques, such as lithography-based patterning/masking and/or etching.

The flowchart begins at block 702 by receiving a substrate (e.g., a silicon substrate or wafer).

The flowchart then proceeds to block 704 to form a superlattice over the substrate, which may include alternating layers of silicon germanium (SiGe) and silicon (Si).

The flowchart then proceeds to block 706 to recess (e.g., etch) the superlattice in the source/drain regions to form superlattice “fins.”

The flowchart then proceeds to block 708 to form a dummy gate and a gate spacer. The dummy gate may be formed over the superlattice fins, and the gate spacer may be formed around the dummy gate and on the sidewalls of the superlattice fins in the SiGe layers.

The flowchart then proceeds to block 710 to form partial source/drain structures with epitaxially-grown arsenic-doped silicon. The source/drain structures are considered “partial” source/drain structures because they are missing a phosphorus component—either a phosphorus implant or cap—which will be added later in the process flow. Moreover, for the phosphorus implant, the partial source/drain structures may be full size, but for the phosphorus cap, they may be shorter than they otherwise would be to accommodate the phosphorus cap that will be added on top.

The flowchart then proceeds to block 712 to remove the dummy gate.

The flowchart then proceeds to block 714 to etch the silicon germanium superlattice layers to release the silicon layers, thus forming silicon nanoribbons that serve as the transistor channel.

The flowchart then proceeds to block 716 to form a gate over the channel (e.g., a gate-all-around (GAA) structure with a high-k dielectric and a gate metal).

The flowchart then proceeds to block 718 to add a phosphorus implant or a phosphorus-doped capping layer to the partial source/drain structures. For example, the phosphorus implant may include phosphorus ions implanted in the partial source/drain structures using ion implantation techniques. Alternatively, the phosphorus-doped capping layer may include a layer of epitaxially grown silicon doped with phosphorus, which may be formed over the partial source/drain structures.

The flowchart then proceeds to block 720 to form source, drain, and gate contacts, which are electrically coupled to the contact regions of the source, drain, and gate structures, respectively. In particular, the source/drain contacts may make contact with the contact regions of the respective source/drain structures, which include either the phosphorus implants or phosphorus-doped capping layer.

The flowchart then proceeds to block 722 to perform any remaining processing, such as inter-layer dielectric (ILD) filling and planarization, interconnect formation, interconnect bump formation, singulation, packaging, etc. For example, in wafer-or panel-level process flows, the completed wafer or panel may be diced to singulate the IC dies on the wafer or panel. The singulated IC dies may then be incorporated into an IC package, circuit board, electronic device, system, etc.

At this point, the flowchart may be complete. In some embodiments, however, the flowchart may restart and/or certain blocks may be repeated. For example, in some embodiments, the flowchart may restart at block 702 to continue forming semiconductor devices that include arsenic-doped source/drain structures with phosphorus-doped contact regions.

### Example Integrated Circuit Embodiments

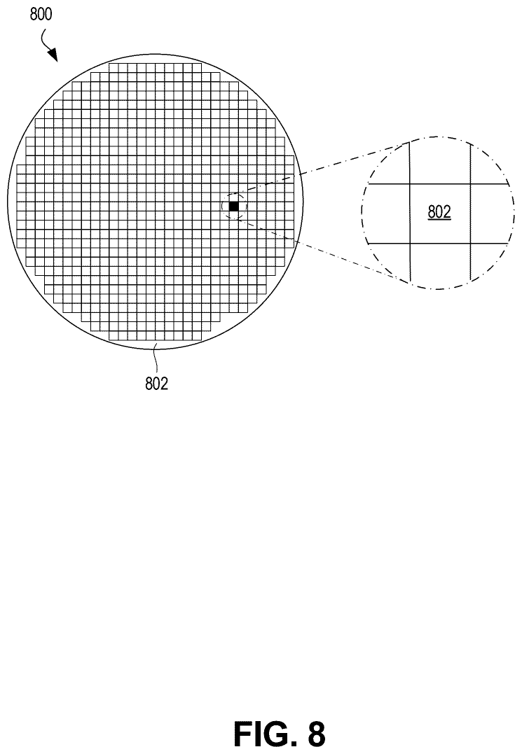

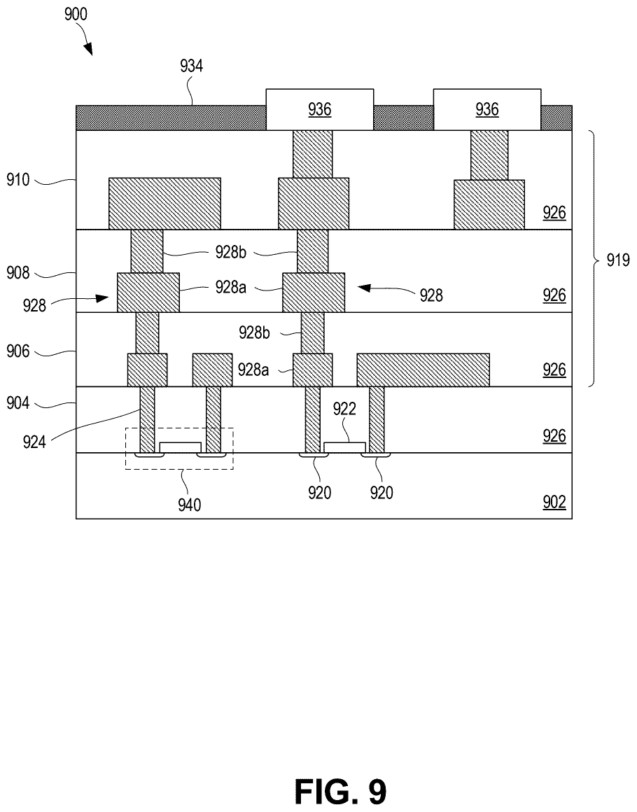

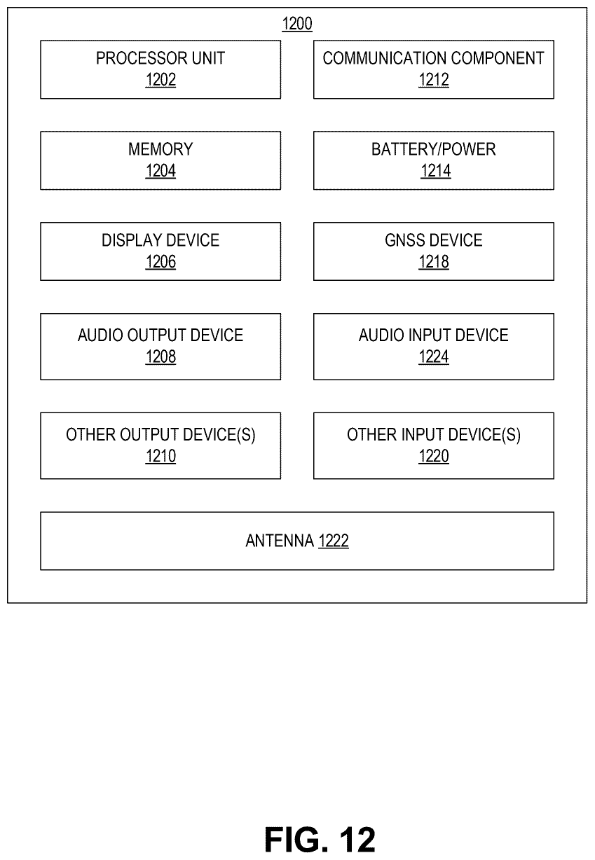

FIG. 8 is a top view of a wafer 800 and dies 802 that may be included in, or may include, any of the embodiments disclosed herein. In some embodiments, for example, the dies 802 may include one or more transistors with arsenic-doped sources/drains and phosphorus-doped contact regions (e.g., transistors 100, 300, 500, 600). The wafer 800 may be composed of semiconductor material and may include one or more dies 802 having integrated circuit structures formed on a surface of the wafer 800. The individual dies 802 may be a repeating unit of an integrated circuit product that includes any suitable integrated circuit. After the fabrication of the semiconductor product is complete, the wafer 800 may undergo a singulation process in which the dies 802 are separated from one another to provide discrete “chips” of the integrated circuit product. The die 802 may be any of the dies disclosed herein. The die 802 may include one or more transistors (e.g., some of the transistors 940 of FIG. 9, discussed below), supporting circuitry to route electrical signals to the transistors, passive components (e.g., signal traces, resistors, capacitors, or inductors), and/or any other integrated circuit components. In some embodiments, the wafer 800 or the die 802 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 802. For example, a memory array formed by multiple memory devices may be formed on a same die 802 as a processor unit (e.g., the processor unit 1202 of FIG. 12) or other logic that is configured to store information in the memory devices or execute instructions stored in the memory array. Various ones of the microelectronic assemblies disclosed herein may be manufactured using a die-to-wafer assembly technique in which some dies are attached to a wafer 800 that include others of the dies, and the wafer 800 is subsequently singulated.

FIG. 9 is a cross-sectional side view of an integrated circuit device 900 that may include, or may be included in, any of the embodiments disclosed herein (e.g., transistors 100, 300, 500, 600, dies 802). One or more of the integrated circuit devices 900 may be included in one or more dies 802 (FIG. 8). The integrated circuit device 900 may be formed on a die substrate 902 (e.g., the wafer 800 of FIG. 8) and may be included in a die (e.g., the die 802 of FIG. 8). The die substrate 902 may be a semiconductor substrate composed of semiconductor material systems including, for example, n-type or p-type materials systems (or a combination of both). The die substrate 902 may include, for example, a crystalline substrate formed using a bulk silicon or a silicon-on-insulator (SOI) substructure. In some embodiments, the die substrate 902 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 902. Although a few examples of materials from which the die substrate 902 may be formed are described here, any material that may serve as a foundation for an integrated circuit device 900 may be used. The die substrate 902 may be part of a singulated die (e.g., the dies 802 of FIG. 8) or a wafer (e.g., the wafer 800 of FIG. 8).

The integrated circuit device 900 may include one or more device layers 904 disposed on the die substrate 902. The device layer 904 may include features of one or more transistors 940 (e.g., metal oxide semiconductor field-effect transistors (MOSFETs)) formed on the die substrate 902. The transistors 940 may include, for example, one or more source and/or drain (S/D) regions 920, a gate 922 to control current flow between the S/D regions 920, and one or more S/D contacts 924 to route electrical signals to/from the S/D regions 920. The transistors 940 may include additional features not depicted for the sake of clarity, such as device isolation regions, gate contacts, and the like. The transistors 940 are not limited to the type and configuration depicted in FIG. 9 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

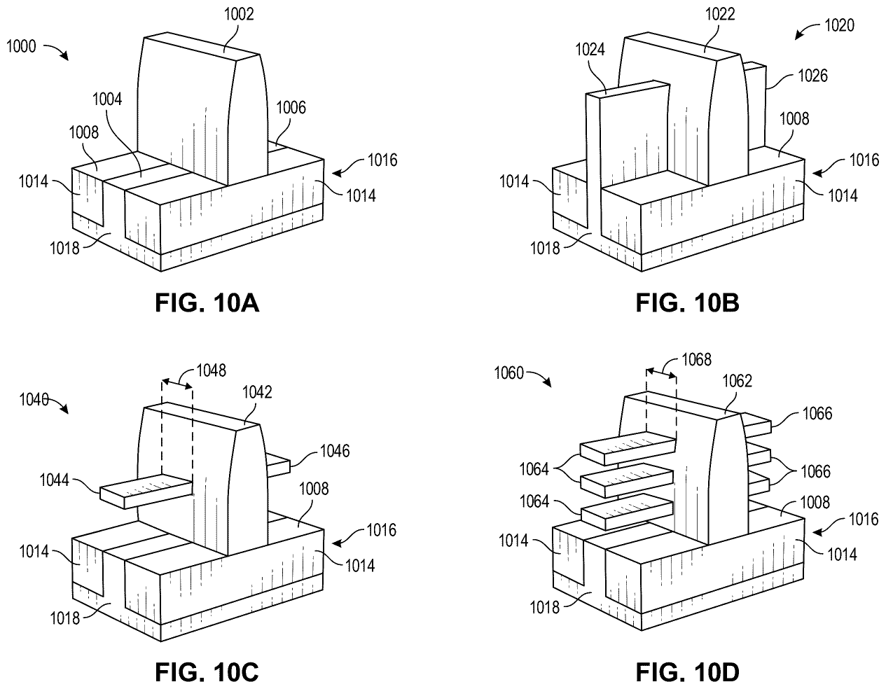

FIGS. 10A-D are simplified perspective views of example planar, FinFET, gate-all-around, and stacked gate-all-around transistors. In some embodiments, these transistors may be implemented with arsenic-doped sources/drains that include phosphorus-doped contact regions (e.g., similar to transistors 100, 300, 500, 600). The transistors illustrated in FIGS. 10A-10D are formed on a substrate 1016 having a surface 1008. Isolation regions 1014 separate the source and drain regions of the transistors from other transistors and from a bulk region 1018 of the substrate 1016.

FIG. 10A is a perspective view of an example planar transistor 1000 comprising a gate 1002 that controls current flow between a source region 1004 and a drain region 1006. The transistor 1000 is planar in that the source region 1004 and the drain region 1006 are planar with respect to the substrate surface 1008.

FIG. 10B is a perspective view of an example FinFET transistor 1020 comprising a gate 1022 that controls current flow between a source region 1024 and a drain region 1026. The transistor 1020 is non-planar in that the source region 1024 and the drain region 1026 comprise “fins” that extend upwards from the substrate surface 1018. As the gate 1022 encompasses three sides of the semiconductor fin that extends from the source region 1024 to the drain region 1026, the transistor 1020 can be considered a tri-gate transistor. FIG. 10B illustrates one S/D fin extending through the gate 1022, but multiple S/D fins can extend through the gate of a FinFET transistor.

FIG. 10C is a perspective view of a gate-all-around (GAA) transistor 1040 comprising a gate 1042 that controls current flow between a source region 1044 and a drain region 1046. The transistor 1040 is non-planar in that the source region 1044 and the drain region 1046 are elevated from the substrate surface 1028.

FIG. 10D is a perspective view of a GAA transistor 1060 comprising a gate 1062 that controls current flow between multiple elevated source regions 1064 and multiple elevated drain regions 1066. The transistor 1060 is a stacked GAA transistor as the gate controls the flow of current between multiple elevated S/D regions stacked on top of each other. The transistors 1040 and 1060 are considered gate-all-around transistors as the gates encompass all sides of the semiconductor portions that extends from the source regions to the drain regions. The transistors 1040 and 1060 can alternatively be referred to as nanowire, nanosheet, or nanoribbon transistors depending on the width (e.g., widths 1048 and 1068 of transistors 1040 and 1060, respectively) of the semiconductor portions extending through the gate.

Returning to FIG. 9, a transistor 940 may include a gate 922 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 940 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 940 along the source-channel-drain direction, the gate electrode may consist of a U-shaped structure that includes a bottom portion substantially parallel to the surface of the die substrate 902 and two sidewall portions that are substantially perpendicular to the top surface of the die substrate 902. In other embodiments, at least one of the metal layers that form the gate electrode may simply be a planar layer that is substantially parallel to the top surface of the die substrate 902 and does not include sidewall portions substantially perpendicular to the top surface of the die substrate 902. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 920 may be formed within the die substrate 902 adjacent to the gate 922 of individual transistors 940. The S/D regions 920 may be formed using an implantation/diffusion process or an etching/deposition process, for example. In the former process, dopants such as boron, aluminum, antimony, phosphorus, or arsenic may be ion-implanted into the die substrate 902 to form the S/D regions 920. An annealing process that activates the dopants and causes them to diffuse farther into the die substrate 902 may follow the ion-implantation process. In the latter process, the die substrate 902 may first be etched to form recesses at the locations of the S/D regions 920. An epitaxial deposition process may then be carried out to fill the recesses with material that is used to fabricate the S/D regions 920. In some implementations, the S/D regions 920 may be fabricated using a silicon alloy such as silicon germanium or silicon carbide. In some embodiments, the epitaxially deposited silicon alloy may be doped in situ with dopants such as boron, arsenic, or phosphorus. In some embodiments, the S/D regions 920 may be formed using one or more alternate semiconductor materials such as germanium or a group III-V material or alloy. In further embodiments, one or more layers of metal and/or metal alloys may be used to form the S/D regions 920.

Electrical signals, such as power and/or input/output (I/O) signals, may be routed to and/or from the devices (e.g., transistors 940) of the device layer 904 through one or more interconnect layers disposed on the device layer 904 (illustrated in FIG. 9 as interconnect layers 906-910). For example, electrically conductive features of the device layer 904 (e.g., the gate 922 and the S/D contacts 924) may be electrically coupled with the interconnect structures 928 of the interconnect layers 906-910. The one or more interconnect layers 906-910 may form a metallization stack (also referred to as an “ILD stack”) 919 of the integrated circuit device 900.

The interconnect structures 928 may be arranged within the interconnect layers 906-910 to route electrical signals according to a wide variety of designs; in particular, the arrangement is not limited to the particular configuration of interconnect structures 928 depicted in FIG. 9. Although a particular number of interconnect layers 906-910 is depicted in FIG. 9, embodiments of the present disclosure include integrated circuit devices having more or fewer interconnect layers than depicted.

In some embodiments, the interconnect structures 928 may include lines 928a and/or vias 928b filled with an electrically conductive material such as a metal. The lines 928a may be arranged to route electrical signals in a direction of a plane that is substantially parallel with a surface of the die substrate 902 upon which the device layer 904 is formed. For example, the lines 928a may route electrical signals in a direction in and out of the page and/or in a direction across the page from the perspective of FIG. 9. The vias 928b may be arranged to route electrical signals in a direction of a plane that is substantially perpendicular to the surface of the die substrate 902 upon which the device layer 904 is formed. In some embodiments, the vias 928b may electrically couple lines 928a of different interconnect layers 906-910 together.

The interconnect layers 906-910 may include a dielectric material 926 disposed between the interconnect structures 928, as shown in FIG. 9. In some embodiments, dielectric material 926 disposed between the interconnect structures 928 in different ones of the interconnect layers 906-910 may have different compositions; in other embodiments, the composition of the dielectric material 926 between different interconnect layers 906-910 may be the same. The device layer 904 may include a dielectric material 926 disposed between the transistors 940 and a bottom layer of the metallization stack as well. The dielectric material 926 included in the device layer 904 may have a different composition than the dielectric material 926 included in the interconnect layers 906-910; in other embodiments, the composition of the dielectric material 926 in the device layer 904 may be the same as a dielectric material 926 included in any one of the interconnect layers 906-910.

A first interconnect layer 906 (referred to as Metal 1 or “M1”) may be formed directly on the device layer 904. In some embodiments, the first interconnect layer 906 may include lines 928a and/or vias 928b, as shown. The lines 928a of the first interconnect layer 906 may be coupled with contacts (e.g., the S/D contacts 924) of the device layer 904. The vias 928b of the first interconnect layer 906 may be coupled with the lines 928a of a second interconnect layer 908.

The second interconnect layer 908 (referred to as Metal 2 or “M2”) may be formed directly on the first interconnect layer 906. In some embodiments, the second interconnect layer 908 may include via 928b to couple the lines 928 of the second interconnect layer 908 with the lines 928a of a third interconnect layer 910. Although the lines 928a and the vias 928b are structurally delineated with a line within individual interconnect layers for the sake of clarity, the lines 928a and the vias 928b may be structurally and/or materially contiguous (e.g., simultaneously filled during a dual-damascene process) in some embodiments.

The third interconnect layer 910 (referred to as Metal 3 or “M3”) (and additional interconnect layers, as desired) may be formed in succession on the second interconnect layer 908 according to similar techniques and configurations described in connection with the second interconnect layer 908 or the first interconnect layer 906. In some embodiments, the interconnect layers that are “higher up” in the metallization stack 919 in the integrated circuit device 900 (i.e., farther away from the device layer 904) may be thicker that the interconnect layers that are lower in the metallization stack 919, with lines 928a and vias 928b in the higher interconnect layers being thicker than those in the lower interconnect layers.

The integrated circuit device 900 may include a solder resist material 934 (e.g., polyimide or similar material) and one or more conductive contacts 936 formed on the interconnect layers 906-910. In FIG. 9, the conductive contacts 936 are illustrated as taking the form of bond pads. The conductive contacts 936 may be electrically coupled with the interconnect structures 928 and configured to route the electrical signals of the transistor(s) 940 to external devices. For example, solder bonds may be formed on the one or more conductive contacts 936 to mechanically and/or electrically couple an integrated circuit die including the integrated circuit device 900 with another component (e.g., a printed circuit board). The integrated circuit device 900 may include additional or alternate structures to route the electrical signals from the interconnect layers 906-910; for example, the conductive contacts 936 may include other analogous features (e.g., posts) that route the electrical signals to external components. The conductive contacts 936 may serve as any of the conductive contacts described throughout this disclosure.

In some embodiments in which the integrated circuit device 900 is a double-sided die, the integrated circuit device 900 may include another metallization stack (not shown) on the opposite side of the device layer(s) 904. This metallization stack may include multiple interconnect layers as discussed above with reference to the interconnect layers 906-910, to provide conductive pathways (e.g., including conductive lines and vias) between the device layer(s) 904 and additional conductive contacts (not shown) on the opposite side of the integrated circuit device 900 from the conductive contacts 936. These additional conductive contacts may serve as any of the conductive contacts described throughout this disclosure.

In other embodiments in which the integrated circuit device 900 is a double-sided die, the integrated circuit device 900 may include one or more through silicon vias (TSVs) through the die substrate 902; these TSVs may make contact with the device layer(s) 904, and may provide conductive pathways between the device layer(s) 904 and additional conductive contacts (not shown) on the opposite side of the integrated circuit device 900 from the conductive contacts 936. These additional conductive contacts may serve as any of the conductive contacts described throughout this disclosure. In some embodiments, TSVs extending through the substrate can be used for routing power and ground signals from conductive contacts on the opposite side of the integrated circuit device 900 from the conductive contacts 936 to the transistors 940 and any other components integrated into the die 900, and the metallization stack 919 can be used to route I/O signals from the conductive contacts 936 to transistors 940 and any other components integrated into the die 900.

Multiple integrated circuit devices 900 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

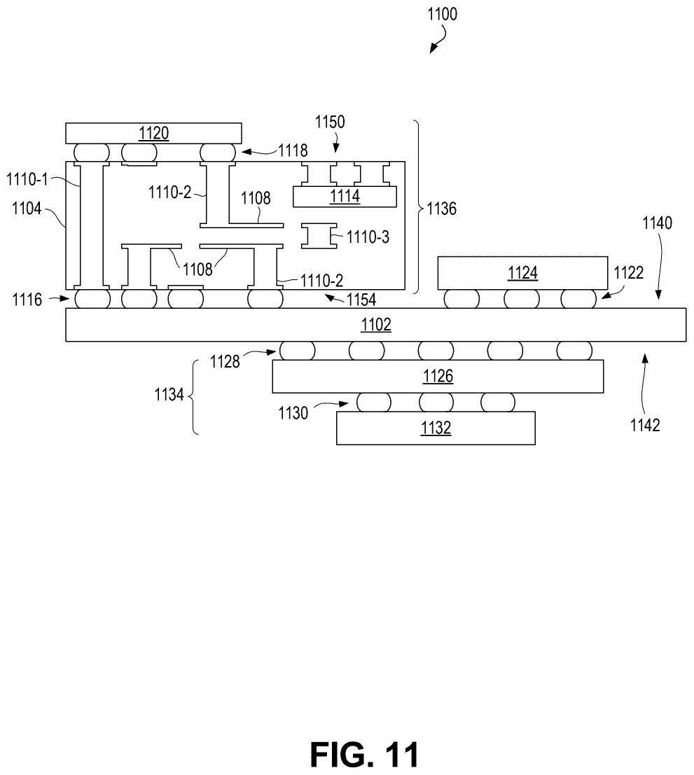

FIG. 11 is a cross-sectional side view of an integrated circuit device assembly 1100 that may include any of the embodiments disclosed herein. In some embodiments, for example, the embedded devices 1114 and/or IC components 1120, 1124, 1126, 1132 of the integrated circuit device assembly 1100 may include one or more transistors with arsenic-doped sources/drains and phosphorus-doped contact regions (e.g., transistors 100, 300, 500, 600).

In some embodiments, the integrated circuit device assembly 1100 may be a microelectronic assembly. The integrated circuit device assembly 1100 includes a number of components disposed on a circuit board 1102 (which may be a motherboard, system board, mainboard, etc.). The integrated circuit device assembly 1100 includes components disposed on a first face 1140 of the circuit board 1102 and an opposing second face 1142 of the circuit board 1102; generally, components may be disposed on one or both faces 1140 and 1142. Any of the integrated circuit components discussed below with reference to the integrated circuit device assembly 1100 may take the form of any suitable ones of the embodiments of the microelectronic assemblies disclosed herein.

In some embodiments, the circuit board 1102 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1102. In other embodiments, the circuit board 1102 may be a non-PCB substrate. The integrated circuit device assembly 1100 illustrated in FIG. 11 includes a package-on-interposer structure 1136 coupled to the first face 1140 of the circuit board 1102 by coupling components 1116. The coupling components 1116 may electrically and mechanically couple the package-on-interposer structure 1136 to the circuit board 1102, and may include solder balls (as shown in FIG. 11), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 1116 may serve as the coupling components illustrated or described for any of the substrate assembly or substrate assembly components described herein, as appropriate.

The package-on-interposer structure 1136 may include an integrated circuit component 1120 coupled to an interposer 1104 by coupling components 1118. The coupling components 1118 may take any suitable form for the application, such as the forms discussed above with reference to the coupling components 1116. Although a single integrated circuit component 1120 is shown in FIG. 11, multiple integrated circuit components may be coupled to the interposer 1104; indeed, additional interposers may be coupled to the interposer 1104. The interposer 1104 may provide an intervening substrate used to bridge the circuit board 1102 and the integrated circuit component 1120.

The integrated circuit component 1120 may be a packaged or unpackaged integrated circuit product that includes one or more integrated circuit dies (e.g., the die 802 of FIG. 8, the integrated circuit device 900 of FIG. 9) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1120, a single monolithic integrated circuit die comprises solder bumps attached to contacts on the die. The solder bumps allow the die to be directly attached to the interposer 1104. The integrated circuit component 1120 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1120 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1120 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1120 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1104 may spread connections to a wider pitch or reroute a connection to a different connection. For example, the interposer 1104 may couple the integrated circuit component 1120 to a set of ball grid array (BGA) conductive contacts of the coupling components 1116 for coupling to the circuit board 1102. In the embodiment illustrated in FIG. 11, the integrated circuit component 1120 and the circuit board 1102 are attached to opposing sides of the interposer 1104; in other embodiments, the integrated circuit component 1120 and the circuit board 1102 may be attached to a same side of the interposer 1104. In some embodiments, three or more components may be interconnected by way of the interposer 1104.

In some embodiments, the interposer 1104 may be formed as a PCB, including multiple metal layers separated from one another by layers of dielectric material and interconnected by electrically conductive vias. In some embodiments, the interposer 1104 may be formed of an epoxy resin, a fiberglass-reinforced epoxy resin, an epoxy resin with inorganic fillers, a ceramic material, or a polymer material such as polyimide. In some embodiments, the interposer 1104 may be formed of alternate rigid or flexible materials that may include the same materials described above for use in a semiconductor substrate, such as silicon, germanium, and other group III-V and group IV materials. The interposer 1104 may include metal interconnects 1108 and vias 1110, including but not limited to through hole vias 1110-1 (that extend from a first face 1150 of the interposer 1104 to a second face 1154 of the interposer 1104), blind vias 1110-2 (that extend from the first or second faces 1150 or 1154 of the interposer 1104 to an internal metal layer), and buried vias 1110-3 (that connect internal metal layers).

In some embodiments, the interposer 1104 can comprise a silicon interposer. Through silicon vias (TSV) extending through the silicon interposer can connect connections on a first face of a silicon interposer to an opposing second face of the silicon interposer. In some embodiments, an interposer 1104 comprising a silicon interposer can further comprise one or more routing layers to route connections on a first face of the interposer 1104 to an opposing second face of the interposer 1104.

The interposer 1104 may further include embedded devices 1114, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1104. The package-on-interposer structure 1136 may take the form of any of the package-on-interposer structures known in the art. In embodiments where the interposer is a non-printed circuit board

The integrated circuit device assembly 1100 may include an integrated circuit component 1124 coupled to the first face 1140 of the circuit board 1102 by coupling components 1122. The coupling components 1122 may take the form of any of the embodiments discussed above with reference to the coupling components 1116, and the integrated circuit component 1124 may take the form of any of the embodiments discussed above with reference to the integrated circuit component 1120.

The integrated circuit device assembly 1100 illustrated in FIG. 11 includes a package-on-package structure 1134 coupled to the second face 1142 of the circuit board 1102 by coupling components 1128. The package-on-package structure 1134 may include an integrated circuit component 1126 and an integrated circuit component 1132 coupled together by coupling components 1130 such that the integrated circuit component 1126 is disposed between the circuit board 1102 and the integrated circuit component 1132. The coupling components 1128 and 1130 may take the form of any of the embodiments of the coupling components 1116 discussed above, and the integrated circuit components 1126 and 1132 may take the form of any of the embodiments of the integrated circuit component 1120 discussed above. The package-on-package structure 1134 may be configured in accordance with any of the package-on-package structures known in the art.

FIG. 12 is a block diagram of an example electrical device 1200 that may include one or more of the embodiments disclosed herein. For example, any suitable ones of the components of the electrical device 1200 may include one or more of the transistors 100, 300, 500, 600, integrated circuit device assemblies 1100, integrated circuit components 1120, integrated circuit devices 900, or integrated circuit dies 802 disclosed herein. A number of components are illustrated in FIG. 12 as included in the electrical device 1200, but any one or more of these components may be omitted or duplicated, as suitable for the application. In some embodiments, some or all of the components included in the electrical device 1200 may be attached to one or more motherboards mainboards, or system boards. In some embodiments, one or more of these components are fabricated onto a single system-on-a-chip (SoC) die.

Additionally, in various embodiments, the electrical device 1200 may not include one or more of the components illustrated in FIG. 12, but the electrical device 1200 may include interface circuitry for coupling to the one or more components. For example, the electrical device 1200 may not include a display device 1206, but may include display device interface circuitry (e.g., a connector and driver circuitry) to which a display device 1206 may be coupled. In another set of examples, the electrical device 1200 may not include an audio input device 1224 or an audio output device 1208, but may include audio input or output device interface circuitry (e.g., connectors and supporting circuitry) to which an audio input device 1224 or audio output device 1208 may be coupled.

The electrical device 1200 may include one or more processor units 1202 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1202 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1200 may include a memory 1204, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1204 may include memory that is located on the same integrated circuit die as the processor unit 1202. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1200 can comprise one or more processor units 1202 that are heterogeneous or asymmetric to another processor unit 1202 in the electrical device 1200. There can be a variety of differences between the processing units 1202 in a system in terms of a spectrum of metrics of merit including architectural, microarchitectural, thermal, power consumption characteristics, and the like. These differences can effectively manifest themselves as asymmetry and heterogeneity among the processor units 1202 in the electrical device 1200.

In some embodiments, the electrical device 1200 may include a communication component 1212 (e.g., one or more communication components). For example, the communication component 1212 can manage wireless communications for the transfer of data to and from the electrical device 1200. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1212 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1212 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1212 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1212 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1212 may operate in accordance with other wireless protocols in other embodiments. The electrical device 1200 may include an antenna 1222 to facilitate wireless communications and/or to receive other wireless communications (such as AM or FM radio transmissions).

In some embodiments, the communication component 1212 may manage wired communications, such as electrical, optical, or any other suitable communication protocols (e.g., IEEE 802.3 Ethernet standards). As noted above, the communication component 1212 may include multiple communication components. For instance, a first communication component 1212 may be dedicated to shorter-range wireless communications such as Wi-Fi or Bluetooth, and a second communication component 1212 may be dedicated to longer-range wireless communications such as global positioning system (GPS), EDGE, GPRS, CDMA, WiMAX, LTE, EV-DO, or others. In some embodiments, a first communication component 1212 may be dedicated to wireless communications, and a second communication component 1212 may be dedicated to wired communications.

The electrical device 1200 may include battery/power circuitry 1214. The battery/power circuitry 1214 may include one or more energy storage devices (e.g., batteries or capacitors) and/or circuitry for coupling components of the electrical device 1200 to an energy source separate from the electrical device 1200 (e.g., AC line power).

The electrical device 1200 may include a display device 1206 (or corresponding interface circuitry, as discussed above). The display device 1206 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1200 may include an audio output device 1208 (or corresponding interface circuitry, as discussed above). The audio output device 1208 may include any embedded or wired or wirelessly connected external device that generates an audible indicator, such speakers, headsets, or earbuds.

The electrical device 1200 may include an audio input device 1224 (or corresponding interface circuitry, as discussed above). The audio input device 1224 may include any embedded or wired or wirelessly connected device that generates a signal representative of a sound, such as microphones, microphone arrays, or digital instruments (e.g., instruments having a musical instrument digital interface (MIDI) output). The electrical device 1200 may include a Global Navigation Satellite System (GNSS) device 1218 (or corresponding interface circuitry, as discussed above), such as a Global Positioning System (GPS) device. The GNSS device 1218 may be in communication with a satellite-based system and may determine a geolocation of the electrical device 1200 based on information received from one or more GNSS satellites, as known in the art.

The electrical device 1200 may include other output device(s) 1210 (or corresponding interface circuitry, as discussed above). Examples of the other output device(s) 1210 may include an audio codec, a video codec, a printer, a wired or wireless transmitter for providing information to other devices, or an additional storage device.

The electrical device 1200 may include other input device(s) 1220 (or corresponding interface circuitry, as discussed above). Examples of the other input device(s) 1220 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1200 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a display device (e.g., monitor, television), a set-top box, an entertainment control unit, a video game console, a video playback device, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1200 may be any other electronic device that processes data. In some embodiments, the electrical device 1200 may comprise multiple discrete physical components. Given the range of devices that the electrical device 1200 can be manifested as in various embodiments, in some embodiments, the electrical device 1200 can be referred to as a computing device or a computing system.

While the concepts of the present disclosure are susceptible to various modifications and alternative forms, specific embodiments thereof have been shown by way of example in the drawings and are described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the illustrative figures. Additionally, the inclusion of a structural or method feature in a particular figure is not meant to imply that such feature is required in all embodiments and, in some embodiments, may not be included or may be combined with other features. Further, it should be understood that the various embodiments shown in the figures are illustrative representations and are not necessarily drawn to scale.

Moreover, the illustrations and/or descriptions of various embodiments may be simplified or approximated for ease of understanding, and as a result, they may not necessarily reflect the level of precision nor variation that may be present in actual embodiments. For example, while some figures generally indicate straight lines, right angles, and smooth surfaces, actual implementations of the disclosed embodiments may have less than perfect straight lines and right angles, and some features may have surface topography or otherwise be non-smooth, given real-world limitations of fabrication processes. Similarly, illustrations and/or descriptions of how components are arranged may be simplified or approximated for ease of understanding and may vary by some margin of error in actual embodiments (e.g., due to fabrication processes, etc.).

The terms “substantially,” “close,” “approximately,” “near,” and “about” may refer to being within +/−10% of a target value unless otherwise specified.

Similarly, terms describing spatial relationships, such as “perpendicular,” “orthogonal,” or “coplanar,” may refer to being substantially within the described spatial relationships (e.g., within +/−10 degrees of orthogonality).

Certain terminology may also be used in the foregoing description for the purpose of reference only, and thus are not intended to be limiting. For example, terms such as “upper,” “lower,” “above,” “below,” “bottom,” and “top” refer to directions in the drawings to which reference is made. Terms such as “front,” “back,” “rear,” and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

In some embodiments, the phrase “A is located on B” or the phrase “A is adjacent to B” means that at least a part of A is in direct physical contact or indirect physical contact (having one or more other features between A and B) with at least a part of B. Moreover, the phrase “B is between A and C” means that at least part of B is in or along a space separating A and C and that at least part of B is in direct or indirect physical contact with A and C.

The terms “coupled” and “connected” may refer to either a direct or indirect connection, such as a direct electrical, mechanical, or magnetic connection, or an indirect connection through one or more passive or active intermediary elements, components, or devices.

The phrases “in an embodiment,” “according to some embodiments,” “in accordance with embodiments,” “in embodiments,” and the like may each refer to one or more of the same or different embodiments.

The terms “comprises,” “comprising,” “includes,” “including,” “having” and the like specify the presence of the stated elements (e.g., features, components, materials, steps, operations) but do not preclude the presence or addition of one or more other elements.

The phrase “and/or” as used herein refers to and encompasses any and all possible combinations of one or more of the associated listed items.

The singular forms “a,” “an,” and “the” are intended to include the plural forms as well, unless the context clearly indicates otherwise. For example, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

As used herein, “electrically conductive” in some examples may refer to a property of a material having an electrical conductivity greater than or equal to 107 Siemens per meter (S/m) at 20 degrees Celsius. Examples of such materials include Cu, Ag, Al, Au, W, Zn, and Ni.

The terms “circuit” or “circuitry,” as used in any embodiment herein may comprise, for example, singly or in any combination, hardwired circuitry, programmable circuitry such as computer processors comprising one or more individual instruction processing cores, state machine circuitry, and/or firmware that stores instructions executed by programmable circuitry. The circuitry may include a processor and/or controller configured to execute one or more instructions to perform one or more operations described herein. The instructions may be embodied as, for example, an application, software, firmware, etc. configured to cause the circuitry to perform any of the aforementioned operations. Software may be embodied as a software package, code, instructions, instruction sets and/or data recorded on a computer-readable storage device. Software may be embodied or implemented to include any number of processes, and processes, in turn, may be embodied or implemented to include any number of threads, etc., in a hierarchical fashion. Firmware may be embodied as code, instructions or instruction sets and/or data that are hard-coded (e.g., nonvolatile) in memory devices. The circuitry may, collectively or individually, be embodied as circuitry that forms part of a larger system, for example, an integrated circuit (IC), an application-specific integrated circuit (ASIC), a system-on-a-chip (SoC), desktop computers, laptop computers, tablet computers, servers, smart phones, etc. Other embodiments may be implemented as software executed by a programmable control device. In such cases, the terms “circuit” or “circuitry” are intended to include a combination of software and hardware such as a programmable control device or a processor capable of executing the software. As described herein, various embodiments may be implemented using hardware elements, software elements, or any combination thereof. Examples of hardware elements may include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, chip sets, and so forth.

For purposes of some embodiments, the transistors in various circuits and logic blocks described herein may be metal oxide semiconductor (MOS) transistors or their derivatives, where the MOS transistors include drain, source, gate, and/or bulk terminals. The transistors and/or the MOS transistor derivatives also include Tri-Gate and FinFET transistors, Gate All Around Cylindrical Transistors, Tunneling FET (TFET), Square Wire, or Rectangular Ribbon Transistors, ferroelectric FET (FeFETs), or other devices implementing transistor functionality like carbon nanotubes or spintronic devices. MOSFET symmetrical source and drain terminals are identical terminals and may be used interchangeably herein. A TFET device, on the other hand, has asymmetric Source and Drain terminals. Those skilled in the art will appreciate that other transistors, for example, Bi-polar junction transistors—BJT PNP/NPN, BiCMOS, CMOS, eFET, etc., may be used without departing from the scope of the disclosure. The term “MN” indicates an n-type transistor (e.g., NMOS, NPN BJT, etc.) and the term “MP” indicates a p-type transistor (e.g., PMOS, PNP BJT, etc.). Moreover, in some embodiments, spintronic logic devices (e.g., magnetoelectric spin-orbit (MESO) logic devices) may be used in addition to, or as an alternative to, MOS transistors.

In the corresponding drawings of the embodiments, signals, currents, electrical biases, or magnetic or electrical polarities may be represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, polarity, current, voltage, etc., as dictated by design needs or preferences, may actually comprise one or more signals that may travel in either direction and may be implemented with any suitable type of signal scheme.

In the foregoing description, numerous specific details are set forth, such as specific integration and material regimes, in order to provide a thorough understanding of embodiments of the present disclosure. It will be apparent to one skilled in the art that embodiments of the present disclosure may be practiced without these specific details. In other instances, well-known features, such as integrated circuit design layouts, may not be described in detail in order to avoid unnecessarily obscuring embodiments of the present disclosure.

It is to be appreciated that the layers and materials described above are typically formed on or above an underlying semiconductor substrate or structure, such as underlying device layer(s) of an integrated circuit. In an embodiment, an underlying semiconductor substrate represents a general workpiece object used to manufacture integrated circuits. The semiconductor substrate often includes a wafer or other piece of silicon or another semiconductor material. Suitable semiconductor substrates include, but are not limited to, single crystal silicon, polycrystalline silicon and silicon on insulator (SOI), as well as similar substrates formed of other semiconductor materials. The semiconductor substrate, depending on the stage of manufacture, often includes transistors, integrated circuitry, and the like. The substrate may also include semiconductor materials, metals, dielectrics, dopants, and other materials commonly found in semiconductor substrates. Furthermore, the structures depicted above may be fabricated on underlying lower level back end of line (BEOL) interconnect layers.

Embodiments disclosed herein may be used to manufacture a wide variety of different types of integrated circuits and/or microelectronic devices. Examples of such integrated circuits include, but are not limited to, processors, chipset components, graphics processors, digital signal processors, microcontrollers, and the like. In other embodiments, semiconductor memory may be manufactured. Moreover, the integrated circuits or other microelectronic devices may be used in a wide variety of electronic devices known in the art. For example, in computer systems (e.g., desktop, laptop, server), cellular phones, personal electronics, etc. The integrated circuits may be coupled with a bus and other components in the systems. For example, a processor may be coupled by one or more buses to a memory, a chipset, etc. Each of the processor, the memory, and the chipset, may potentially be manufactured using the approaches disclosed herein.

The disclosed embodiments may be implemented, in some cases, in hardware, firmware, software, or any combination thereof. The disclosed embodiments may also be implemented as instructions carried by or stored on one or more transitory or non-transitory machine-readable (e.g., computer-readable) storage media, which may be read and executed by one or more processors. A machine-readable storage medium may be embodied as any storage device, mechanism, or other physical structure for storing or transmitting information in a form readable by a machine, including volatile or non-volatile memory (e.g., random access memory (RAM), flash memory), hard drives (e.g., hard disk drive (HDD), solid state drive (SSD)), media discs, or combination thereof.

### EXAMPLES

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.
Example 1 includes a semiconductor device, comprising: an epitaxial structure, wherein the epitaxial structure comprises silicon, arsenic, and phosphorus, wherein phosphorus is concentrated in a contact region of the epitaxial structure; and a conductive contact coupled to the contact region of the epitaxial structure, wherein the conductive contact comprises metal.
Example 2 includes the semiconductor device of Example 1, wherein: the epitaxial structure further comprises silicon doped with arsenic; and the contact region comprises silicon doped with arsenic and phosphorus.
Example 3 includes the semiconductor device of Example 2, wherein the contact region further comprises phosphorus ions implanted in silicon.
Example 4 includes the semiconductor device of Example 3, wherein a distribution of the phosphorus ions is approximately Gaussian.
Example 5 includes the semiconductor device of any of Examples 2-4, wherein the epitaxial structure has a substantially uniform concentration of arsenic.
Example 6 includes the semiconductor device of any of Examples 2-5, wherein the epitaxial structure has a concentration of arsenic of at least 5e21 atoms per cubic centimeter.
Example 7 includes the semiconductor device of Example 1, wherein: the epitaxial structure further comprises a first epitaxial layer and a second epitaxial layer, wherein the first epitaxial layer comprises silicon doped with arsenic, and wherein the second epitaxial layer comprises silicon doped with phosphorus; and the conductive contact is coupled to the second epitaxial layer, wherein the contact region is in the second epitaxial layer.
Example 8 includes the semiconductor device of Example 7, wherein: the first epitaxial layer has a substantially uniform concentration of arsenic; and the second epitaxial layer has a substantially uniform concentration of phosphorus.
Example 9 includes the semiconductor device of any of Examples 7-8, wherein the first epitaxial layer has a concentration of arsenic of at least 5e21 atoms per cubic centimeter.
Example 10 includes the semiconductor device of any of Examples 7-9, wherein: the first epitaxial layer does not comprise phosphorus; and the second epitaxial layer does not comprise arsenic.
Example 11 includes the semiconductor device of any of Examples 7-10, wherein a thickness of the second epitaxial layer is in a range of 10%-40% of a thickness of the first epitaxial layer.
Example 12 includes the semiconductor device of any of Examples 1-11, further comprising an n-type metal-oxide-semiconductor (NMOS) transistor, wherein the NMOS transistor comprises the epitaxial structure and the conductive contact, wherein the epitaxial structure is an n-type epitaxial structure.
Example 13 includes the semiconductor device of Example 12, wherein the NMOS transistor is a nanoribbon transistor, a gate-all-around (GAA) transistor, a fin field-effect transistor (FinFET), a planar transistor, or a two-dimensional transistor.
Example 14 includes an electronic device, comprising: one or more transistors, wherein the respective transistors comprise: a plurality of source or drain structures, wherein the respective source or drain structures comprise a first region and a second region, wherein the first region comprises silicon doped with arsenic, wherein the second region comprises silicon doped with phosphorus, and wherein the second region is adjacent to a contact interface between the respective source or drain structures and respective conductive contacts of a plurality of conductive contacts; and the plurality of conductive contacts, wherein the respective conductive contacts comprise metal, and wherein the respective conductive contacts are coupled to the second region of the respective source or drain structures at the contact interface.
Example 15 includes the electronic device of Example 14, wherein the second region further comprises silicon implanted with phosphorus ions.
Example 16 includes the electronic device of Example 15, wherein a distribution of the phosphorus ions is approximately Gaussian.
Example 17 includes the electronic device of any of Examples 14-16, wherein the second region further comprises silicon doped with arsenic and phosphorus.
Example 18 includes the electronic device of Example 17, wherein the respective source or drain structures have a substantially uniform concentration of arsenic.
Example 19 includes the electronic device of any of Examples 17-18, wherein the respective source or drain structures have a concentration of arsenic of at least 5e21 atoms per cubic centimeter.
Example 20 includes the electronic device of Example 14, wherein the first region is a first epitaxial layer and the second region is a second epitaxial layer, wherein the first epitaxial layer has a substantially uniform concentration of arsenic, and wherein the second epitaxial layer has a substantially uniform concentration of phosphorus.
Example 21 includes the electronic device of Example 20, wherein the first epitaxial layer has a concentration of arsenic of at least 5e21 atoms per cubic centimeter.
Example 22 includes the electronic device of any of Examples 20-21, wherein: the first epitaxial layer does not comprise phosphorus; and the second epitaxial layer does not comprise arsenic.
Example 23 includes the electronic device of any of Examples 20-22, wherein a thickness of the second epitaxial layer is in a range of 10%-40% of a thickness of the first epitaxial layer.
Example 24 includes the electronic device of any of Examples 14-23, wherein the one or more transistors are one or more n-type metal-oxide-semiconductor (NMOS) transistors, wherein the respective NMOS transistors further comprise: one or more channels between the source or drain structures; and one or more gates coupled to the one or more channels.
Example 25 includes the electronic device of any of Examples 14-24, wherein the one or more transistors include one or more of a nanoribbon transistor, a gate-all-around (GAA) transistor, a fin field-effect transistor (FinFET), a planar transistor, or a two-dimensional transistor.
Example 26 includes the electronic device of any of Examples 14-25, further comprising: a circuit board; and an integrated circuit coupled to the circuit board, wherein the integrated circuit comprises processing circuitry, memory circuitry, storage circuitry, or communication circuitry, wherein one or more of the transistors are comprised in the processing circuitry, the memory circuitry, the storage circuitry, or the communication circuitry.
Example 27 includes a method, comprising: forming a plurality of epitaxial structures, wherein the respective epitaxial structures comprise silicon doped with arsenic; forming a channel between the epitaxial structures, wherein the channel comprises silicon; forming a gate over the channel; forming a plurality of implants in the epitaxial structures or forming a plurality of epitaxial layers over the epitaxial structures, wherein the respective implants comprise phosphorous or the respective epitaxial layers comprise silicon doped with phosphorous; and forming a plurality of conductive contacts, wherein the respective conductive contacts are coupled to the respective epitaxial structures or the respective epitaxial layers.
Example 28 includes the method of Example 27, further comprising forming the plurality of implants in the epitaxial structures, wherein forming the plurality of implants in the epitaxial structures comprises implanting phosphorus ions into the epitaxial structures.
Example 29 includes the method of Example 27, further comprising forming the plurality of epitaxial layers over the epitaxial structures, wherein the respective epitaxial layers comprise silicon doped with phosphorous.
Example 30 includes the method of any of Examples 27-29, wherein: the implants are formed after the gate is formed; or the epitaxial layers are formed after the gate is formed.
Example 31 includes the method of any of Examples 27-30, wherein the method is a method of forming a transistor, wherein the transistor comprises: the epitaxial structures, the channel, the gate, and the conductive contacts; and the implants or the epitaxial layers.

1. A semiconductor device, comprising:
an epitaxial structure, wherein the epitaxial structure comprises silicon, arsenic, and phosphorus, wherein phosphorus is concentrated in a contact region of the epitaxial structure; and
a conductive contact coupled to the contact region of the epitaxial structure, wherein the conductive contact comprises metal.

2. The semiconductor device of claim 1, wherein:
the epitaxial structure further comprises silicon doped with arsenic; and
the contact region comprises silicon doped with arsenic and phosphorus.

3. The semiconductor device of claim 2, wherein the contact region further comprises phosphorus ions implanted in silicon.

4. The semiconductor device of claim 3, wherein a distribution of the phosphorus ions is approximately Gaussian.

5. The semiconductor device of claim 2, wherein the epitaxial structure has a substantially uniform concentration of arsenic.

6. The semiconductor device of claim 2, wherein the epitaxial structure has a concentration of arsenic of at least 5e²¹ atoms per cubic centimeter.

7. The semiconductor device of claim 1, wherein:
the epitaxial structure further comprises a first epitaxial layer and a second epitaxial layer, wherein the first epitaxial layer comprises silicon doped with arsenic, and wherein the second epitaxial layer comprises silicon doped with phosphorus; and
the conductive contact is coupled to the second epitaxial layer, wherein the contact region is in the second epitaxial layer.

8. The semiconductor device of claim 7, wherein:
the first epitaxial layer has a substantially uniform concentration of arsenic; and
the second epitaxial layer has a substantially uniform concentration of phosphorus.

9. The semiconductor device of claim 7, wherein a thickness of the second epitaxial layer is in a range of 10%-40% of a thickness of the first epitaxial layer.

10. The semiconductor device of claim 1, further comprising an n-type metal-oxide-semiconductor (NMOS) transistor, wherein the NMOS transistor comprises the epitaxial structure and the conductive contact, wherein the epitaxial structure is an n-type epitaxial structure.

11. An electronic device, comprising:
one or more transistors, wherein the respective transistors comprise:
a plurality of source or drain structures, wherein the respective source or drain structures comprise a first region and a second region, wherein the first region comprises silicon doped with arsenic, wherein the second region comprises silicon doped with phosphorus, and wherein the second region is adjacent to a contact interface between the respective source or drain structures and respective conductive contacts of a plurality of conductive contacts; and
the plurality of conductive contacts, wherein the respective conductive contacts comprise metal, and wherein the respective conductive contacts are coupled to the second region of the respective source or drain structures at the contact interface.

12. The electronic device of claim 11, wherein the second region further comprises silicon implanted with phosphorus ions.

13. The electronic device of claim 11, wherein the second region further comprises silicon doped with arsenic and phosphorus.

14. The electronic device of claim 11, wherein the first region is a first epitaxial layer and the second region is a second epitaxial layer, wherein the first epitaxial layer has a substantially uniform concentration of arsenic, and wherein the second epitaxial layer has a substantially uniform concentration of phosphorus.

15. The electronic device of claim 11, wherein the one or more transistors are one or more n-type metal-oxide-semiconductor (NMOS) transistors, wherein the respective NMOS transistors further comprise:
one or more channels between the source or drain structures; and
one or more gates coupled to the one or more channels.

16. The electronic device of claim 11, further comprising:
a circuit board; and
an integrated circuit coupled to the circuit board, wherein the integrated circuit comprises processing circuitry, memory circuitry, storage circuitry, or communication circuitry, wherein one or more of the transistors are comprised in the processing circuitry, the memory circuitry, the storage circuitry, or the communication circuitry.

17. A method, comprising:
forming a plurality of epitaxial structures, wherein the respective epitaxial structures comprise silicon doped with arsenic;
forming a channel between the epitaxial structures, wherein the channel comprises silicon;
forming a gate over the channel;
forming a plurality of implants in the epitaxial structures or forming a plurality of epitaxial layers over the epitaxial structures, wherein the respective implants comprise phosphorous or the respective epitaxial layers comprise silicon doped with phosphorous; and
forming a plurality of conductive contacts, wherein the respective conductive contacts are coupled to the respective epitaxial structures or the respective epitaxial layers.

18. The method of claim 17, further comprising forming the plurality of implants in the epitaxial structures, wherein forming the plurality of implants in the epitaxial structures comprises implanting phosphorus ions into the epitaxial structures.

19. The method of claim 17, further comprising forming the plurality of epitaxial layers over the epitaxial structures, wherein the respective epitaxial layers comprise silicon doped with phosphorous.

20. The method of claim 17, wherein the method is a method of forming a transistor, wherein the transistor comprises:
the epitaxial structures, the channel, the gate, and the conductive contacts; and
the implants or the epitaxial layers.
